(19) United States
(12) Patent Application Publication
(10) Pub. No.: US 2024/0215225 A1
(43) Pub. Date: Jun. 27, 2024

(54) SEMICONDUCTOR DEVICE INCLUDING SPACER STRUCTURE HAVING AIR GAP

(71) Applicant: Samsung Electronics Co., Ltd., Suwon-si (KR)

(72) Inventors: Teawon Kim, Suwon-si (KR); Seohee Park, Suwon-si (KR); Yongsuk Tak, Suwon-si (KR); Minkyung Kang, Suwon-si (KR); Joonnyung Heo, Suwon-si (KR)

(21) Appl. No.: 18/391,835

(22) Filed: Dec. 21, 2023

(30) Foreign Application Priority Data
Dec. 23, 2022 (KR) 10-2022-0182798

(51) Int. Cl. H10B 12/00; H01L 21/764

(52) U.S. Cl. CPC H10B 12/482; H01L 21/764; H10B 12/0335; H10B 12/315

(57) ABSTRACT

A semiconductor device includes a line structure on the lower structure and including a conductive pattern and an insulating capping pattern on the conductive pattern, a contact structure including a lower portion adjacent to a side surface of the line structure and an upper portion on the lower portion, a spacer structure between a side surface of the lower portion of the contact structure and the side surface of the line structure, an insulating separation pattern on the spacer structure, and a protective layer between the upper portion of the contact structure and the insulating separation pattern. The spacer structure includes an internal spacer, an external spacer, and an air gap between the internal spacer and the external spacer. Regions of the internal spacer and the external spacer exposed by the air gap include an oxide. The insulating separation pattern seals at least a portion of an upper portion of the air gap.

### CROSS-REFERENCE TO RELATED APPLICATION(S)

This application claims benefit of priority to Korean Patent Application No. 10-2022-0182798 filed on Dec. 23, 2022, in the Korean Intellectual Property Office, the disclosure of which is herein incorporated by reference in its entirety.

### BACKGROUND

Example embodiments relate to a semiconductor device including a spacer structure having an air gap and a manufacturing method thereof.

According to the tendency for high integration of semiconductor devices, a gap between interconnection lines is gradually narrowing. As the gap between the interconnection lines becomes narrow as described above, there is a problem in that a transmission speed of an electrical signal is delayed due to an RC delay.

### SUMMARY

Example embodiments provide a semiconductor device including a spacer structure that may reduce parasitic capacitance between conductive patterns.

Example embodiments provide a semiconductor device including a spacer structure that may reduce parasitic capacitance between conductive patterns and a protective layer that may protect a surface of a pad pattern from an oxidation process.

Example embodiments provide a method for forming a semiconductor device.

According to example embodiments, a semiconductor device includes: first and second line structures parallel to each other; a plurality of spacer structures, wherein each of the pluraity of spacer structures is disposed on a corresponding side surface of side surfaces of the first and second line structures; a contact structure including a lower portion disposed between the first line structure and the second line structure and an upper portion on the lower portion; an insulating separation pattern on a side surface of the upper portion of the contact structure; and a protective layer including a first protective portion disposed between the insulating separation pattern and the upper portion of the contact structure, wherein the plurality of spacer structures include a first spacer structure on a first side surface of the first line structure and a second spacer structure on a second side surface of the second line structure, the first side surface of the first line structure and the second side surface of the second line structure face each other, at least a portion of the first spacer structure is disposed between the first side surface of the first line structure and the lower portion of the contact structure, and at least a portion of the second spacer structure is disposed between the second side surface of the second line structure and the lower portion of the contact structure, wherein the first spacer structure includes: an internal spacer contacting the first side surface of the first line structure; an external spacer spaced apart from the first side surface of the first line structure; and an air gap between the internal spacer and the external spacer, and wherein the internal spacer includes a first region having an oxide and the external spacer includes a second region having an oxide, and wherein the air gap is disposed between the first region and the second region.

According to example embodiments, a semiconductor device includes: a lower structure; a line structure disposed on the lower structure and including a conductive pattern and an insulating capping pattern on the conductive pattern; a contact structure including a lower portion disposed adjacent to a side surface of the line structure and an upper portion disposed on the lower portion and disposed at a higher level than an upper surface of the line structure; a spacer structure between a side surface of the lower portion of the contact structure and the side surface of the line structure; an insulating separation pattern on the spacer structure; and a protective layer between the upper portion of the contact structure and the insulating separation pattern, wherein the spacer structure includes: an internal spacer; an external spacer; and an air gap between the internal spacer and the external spacer, wherein regions of the internal spacer and the external spacer exposed by the air gap include an oxide, and the insulating separation pattern seals at least a portion of an upper portion of the air gap.

According to example embodiments, a semiconductor device includes: an active region; an isolation region on a side surface of the active region; a gate structure within a gate trench intersecting the active region and extending into the isolation region; a first impurity region and a second impurity region disposed within the active region on opposite sides of the gate structure and spaced apart from each other; first and second line structures extending parallel with each other and disposed at a higher level than the gate structure; a contact structure including a plug pattern disposed between the first and second line structures and electrically connected to the first impurity region, and a pad pattern on the plug pattern and electrically connected to the plug pattern; a plurality of spacer structures, wherein each of the plurality of spacer structures is disposed on a corresponding side surface of side surfaces of the first and second line structures; an insulating separation pattern covering at least a portion of a side surface of the pad pattern; a protective layer, wherein at least a portion of the protective layer is disposed between the insulating separation pattern and the pad pattern; and a data storage structure on the pad pattern, wherein the first line structure includes a first bit line including a bit line contact portion electrically connected to the second impurity region, and a first insulating capping pattern on the first bit line, the second line structure includes a second bit line and a second insulating capping pattern on the second bit line, the first line structure has a first side surface facing the second line structure, the second line structure has a second side surface facing the first line structure, the plurality of spacer structures include a first spacer structure on the first side surface of the first line structure and a second spacer structure on the second side surface of the second line structure, the first spacer structure is disposed between the contact structure and the first line structure, the second spacer structure is disposed between the contact structure and the second line structure, wherein the first spacer structure includes: a first internal spacer; a first external spacer; and a first air gap between the first internal spacer and the first external spacer, and wherein the second spacer structure includes: a second internal spacer; a second external spacer; and a second air gap between the second internal spacer and the second external spacer, the first internal spacer is adjacent to or contacting the first side surface of the first line structure, the first external spacer is adjacent to or contacting the contact structure, the second internal spacer is adjacent to or contacting the second side surface of the second line structure, the second external spacer is adjacent to or contacting the contact structure, the insulating separation pattern seals an upper portion of the first air gap, the plurality of spacer structures further include an upper insulating spacer disposed between the pad pattern and the second insulating capping pattern and defining an upper portion of the second air gap, the pad pattern includes a portion vertically overlapping the second insulating capping pattern and disposed on the second insulating capping pattern, and the first internal spacer, the first external spacer, the second internal spacer, and the second external spacer exposed by the first air gap or second air gap include an oxide.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a top view conceptually illustrating a semiconductor device according to example embodiments of the present disclosure;

FIGS. 2A, 2B, and 3 are conceptual views illustrating a semiconductor device according to an example embodiment of the present disclosure;

FIG. 4 is a graph schematically illustrating concentration gradients of carbon and oxygen of some elements of a semiconductor device according to an example embodiment of the present disclosure;

FIG. 5 is a partially enlarged view conceptually illustrating a modified example of a semiconductor device according to an example embodiment of the present disclosure;

FIGS. 6A, 6B, and 7 are conceptual views illustrating a modified example of a semiconductor device according to an example embodiment of the present disclosure;

FIG. 8 is a partially enlarged view conceptually illustrating a modified example of a semiconductor device according to an example embodiment of the present disclosure;

FIG. 9 is a partially enlarged view conceptually illustrating a modified example of a semiconductor device according to an example embodiment of the present disclosure;

FIG. 10 is a partially enlarged view conceptually illustrating a modified example of a semiconductor device according to an example embodiment of the present disclosure;

FIGS. 11, 12A, 12B, 13A, 13B, 13C, 14A, 14B, 15A, 15B, 16, and 17 are views schematically illustrating an example of a method for forming a semiconductor device according to an example embodiment of the present disclosure; and

FIGS. 18, 19, and 20 are views schematically illustrating an example of a method for forming a semiconductor device according to an example embodiment of the present disclosure.

### DETAILED DESCRIPTION

Hereinafter, the terms such as “upper,” “intermediate,” and “lower” may be replaced with other terms such as “first,” “second,” and “third” and may be used to describe elements of the specification. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

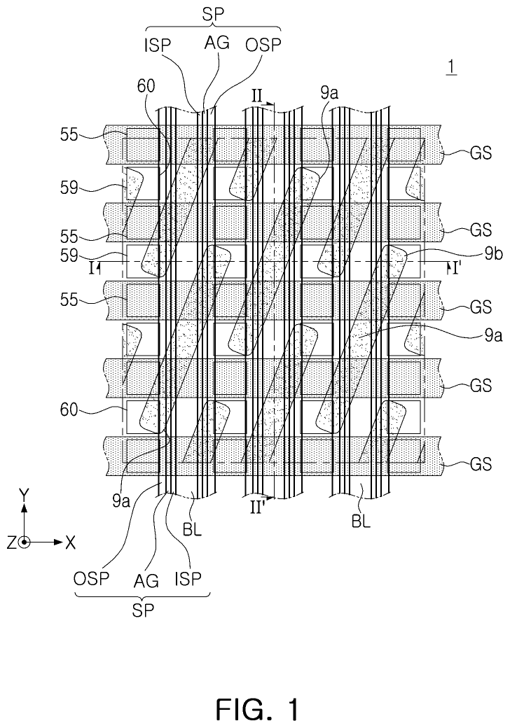

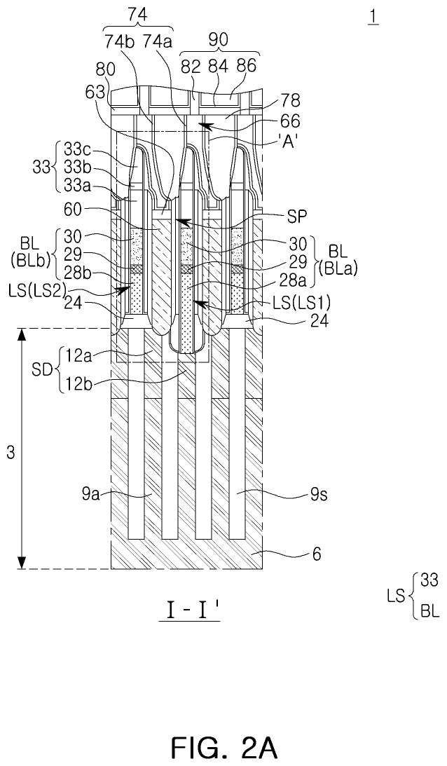

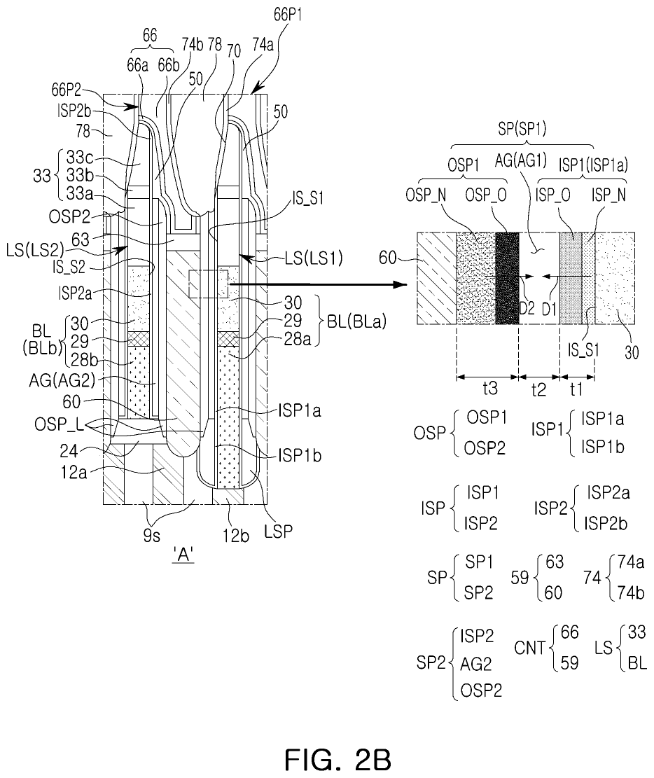

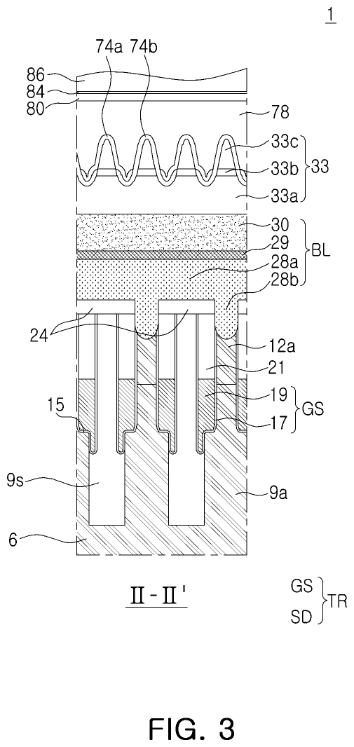

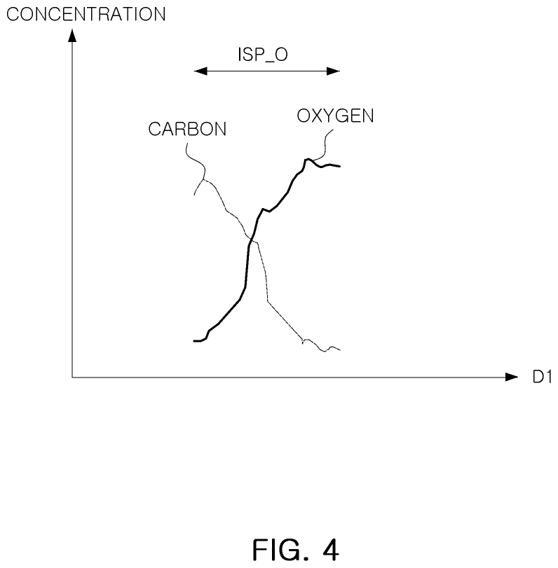

First, referring to FIGS. 1, 2A, 2B, 3, and 4, an example of a semiconductor device according to an example embodiment of the present disclosure will be described. In FIGS. 1 to 4, FIG. 1 is a top view conceptually illustrating a semiconductor device according to example embodiments of the present disclosure, FIG. 2A is a cross-sectional view conceptually illustrating a region taken along line I-I′ of FIG. 1, FIG. 2B is a partially enlarged view of a region indicated by part ‘A’ of FIG. 2A, FIG. 3 is a cross-sectional view conceptually illustrating a region taken along line II-II′ of FIG. 1, and FIG. 4 is a graph schematically illustrating concentration gradients of carbon and oxygen of some elements of a semiconductor device according to an example embodiment of the present disclosure.

Referring to FIGS. 1, 2A, 2B, and 3, a semiconductor device 1 according to an example embodiment may include a lower structure 3. The lower structure 3 may include a substrate 6, an active region 9a on the substrate 6, a device isolation region 9s on a side surface of the active region 9a, a gate trench 15 intersecting the active region 9a and extending into the device isolation region 9s, a gate structure GS in the gate trench 15, and a first impurity region 12a and a second impurity region 12b disposed in the active region 9a on opposite side surfaces of the gate structure GS and spaced apart from each other.

The substrate 6 may be a semiconductor substrate. For example, the substrate 6 may include or may be formed of a group IV semiconductor, a group III-V compound semiconductor, or a group II-VI compound semiconductor. For example, the group IV semiconductor may include silicon, germanium, or silicon-germanium. For example, the substrate 6 may include or may be formed of a silicon material, for example, a single crystalline silicon material. The substrate 6 may be a silicon substrate, a silicon-on-insulator (SOI) substrate, a germanium substrate, a germanium-on-insulator (GOI) substrate, a silicon-germanium substrate, or a substrate including an epitaxial layer.

The device isolation region 9s may be a trench element isolation layer. The device isolation region 9s may be disposed on the substrate 6, and may define the active region 9a. The device isolation region 9s may include or may be formed of an insulating material such as silicon oxide and/or silicon nitride.

The gate structure GS may have a line shape extending in a first direction (X-direction), and the active region 9a may have a bar shape extending in an oblique direction intersecting the first direction (X-direction) while forming an obtuse angle or an acute angle.

A plurality of active regions 9a may be disposed in the lower structure 3. A plurality of gate structures GS may be disposed. One active region 9a of the plurality of active regions 9a may intersect a pair of gate structures GS disposed adjacent to each other among the plurality of gate structures GS.

In the top view, when viewed from one of the active regions 9a, the first impurity region 12a may be disposed in an intermediate portion of the active region 9a, and the second impurity regions 12b may be disposed in opposite end portions of the active region 9a.

Hereinafter, one active region 9a and one gate structure GS will be mainly described.

The gate structure GS may include a gate dielectric layer 17 covering an internal wall of the gate trench 15, and a gate electrode 19 disposed on the gate dielectric layer 17 and partially filling the gate trench 15.

The lower structure 3 may further include a gate capping layer 21 disposed on the gate electrode 19 and filling the remaining portion of the gate trench 15.

The gate dielectric layer 17 may include or may be formed of at least one of silicon oxide and a high-κ dielectric material. The gate electrode 19 may include doped polysilicon, metal, a conductive metal nitride, metal-semiconductor compounds (e.g., metal silicides), a conductive metal oxide, graphene, carbon nanotubes, or a combination thereof. For example, the gate electrode 19 may include or may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, a carbon nanotube, or a combination thereof, but the present disclosure is not limited thereto. The gate electrode 19 may include a single layer or multiple layers of the above-described materials. The gate capping layer 21 may include or may be formed of an insulating material, for example, silicon nitride.

The first and second impurity regions 12a and 12b in the active region 9a may be spaced apart from each other by the gate structure GS, and may be first and second source/drain regions SD. The first and second impurity regions 12a and 12b and the gate structure GS may constitute a transistor TR.

The semiconductor device 1 may further include a buffer pattern 24 and line structures LS.

The buffer pattern 24 may be disposed on the lower structure 3. The buffer pattern 24 may include a plurality of insulating layers sequentially stacked on each other. For example, the buffer pattern 24 may include at least two material layers, for example, a silicon oxide layer and a silicon nitride layer.

The line structures LS may be parallel to each other. Each of the line structures LS may have a line shape extending lengthwise in a second direction (Y-direction) perpendicular to the first direction (X-direction).

Each of the line structures LS may include a conductive pattern BL and an insulating capping pattern 33 on the conductive pattern BL. The conductive pattern BL may be referred to as a conductive line.

In example embodiments, when the semiconductor device 1 is a memory device, the gate electrode 19 may be a word line, and the conductive pattern BL may be a bit line.

Hereinafter, the conductive pattern BL will be described and referred to as a ‘bit line.’

The line structures LS may include a first line structure LS1 and a second line structure LS2 disposed adjacent to each other. The bit line BL of the first line structure LS1 may be referred to as a first bit line BLa, and the insulating capping pattern 33 of the first line structure LS1 may be referred to as a first insulating capping pattern 33. The bit line BL of the second line structure LS2 may be referred to as a second bit line BLb, and the insulating capping pattern 33 of the second line structure LS2 may be referred to as a second insulating capping pattern 33.

Each of the bit lines BL may include a line portion disposed on the buffer pattern 24 and a plug portion penetrating through the buffer pattern 24 and electrically connected to the second impurity region 12b. For example, in the cross-sectional structure illustrated in FIGS. 2A and 2B, the first bit line BLa may include a bit line contact portion electrically connected to the second impurity region 12b, and the second bit line BLb may be disposed on the buffer pattern 24.

The bit lines BL may include doped polysilicon, metal, conductive metal nitride, metal-semiconductor compounds (e.g., metal silicides), metal compounds, a conductive metal oxide, graphene, carbon nano tubes, or a combination thereof. For example, the bit lines BL may include or may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes, or a combination thereof, but the present disclosure is not limited thereto. For example, each of the bit lines BL may include first conductive layers 28a and 28b, a second conductive layer 29, and a third conductive layer 30 that are sequentially stacked. The first conductive layers 28a and 28b may include a plug portion 28a penetrating through the buffer pattern 24 and electrically connected to the second impurity region 12b, and a line portion 28b disposed on the buffer pattern 24.

The first conductive layers 28a and 28b may include or may be formed of doped polysilicon, for example, polysilicon having dopants of an N-type conductivity type. The second conductive layer 29 may include or may be formed of at least one of a metal-semiconductor compound layer (e.g., a metal silicide layer) and a conductive barrier layer. For example, the metal-semiconductor compound layer may include or may be formed of at least one of WSi, TiSi, TaSi, NiSi and CoSi, and the conductive barrier layer may include or may be formed of at least one of TiN, TaN, WN, TiSiN, TaSiN and RuTiN. The third conductive layer 30 may include or may be formed of a metal material such as W.

Each of the insulating capping patterns 33 may be formed of a single layer or a plurality of layers 33a, 33b and 33c that are sequentially stacked. The insulating capping patterns 33 may include or may be formed of a silicon nitride or a silicon nitride-based insulating material.

The semiconductor device 1 may further include spacer structures SP disposed on side surfaces of the line structures LS.

Each of the spacer structures SP may include an internal spacer ISP, an external spacer OSP, and an air gap AG between the internal spacer ISP and the external spacer OSP. In each of the spacer structures SP, an upper end of the air gap AG may be disposed at a higher level than upper surfaces of the bit lines BL.

An example of the spacer structures SP will be described based on a partially enlarged view of FIG. 2B.

In the first and second line structures LS1 and LS2 disposed adjacent to each other, the first line structure LS1 may have a first side surface IS_S1 facing the second line structure LS2, and the second line structure LS2 may have a second side surface IS_S2 facing the first line structure LS1. The spacer structures SP may include a first spacer structure SP1 on the first side surface IS_S1 of the first line structure LS1, and a second spacer structure SP2 on the second side surface IS_S2 of the second line structure LS2. The first spacer structure SP1 may be in contact with the first side surface IS_S1 of the first line structure LS1. The second spacer structure SP2 may be in contact with the second side surface IS_S2 of the second line structure LS2. The term “contact,” as used herein, refers to a direct connection (i.e., touching) unless the context indicates otherwise.

The first spacer structure SP1 may include a lower spacer pattern LSP, a first internal spacer ISP1, a first external spacer OSP1, and a first air gap AG1 between the first internal spacer ISP1 and the first external spacer OSP1.

The lower spacer pattern LSP may be disposed under the first air gap AG1 and the first external spacer OSP1. The lower spacer pattern LSP may cover a side surface of a lower region of the first bit line BLa. The lower spacer pattern LSP may include or may be formed of at least one of SiN and SiCN.

The first internal spacer ISP1 may be adjacent to or in contact with the first side surface IS_S1 of the first line structure L S1. The first inner spacer ISP1 may include a first portion ISP1a exposed by the first air gap AG1 and a second portion ISP1b extending downward from the first portion ISP1a and interposed between the lower spacer pattern LSP and the first bit line BLa to cover a side surface and a bottom surface of the lower spacer pattern LSP. A lower portion of the first air gap AG1 may be defined by the lower spacer pattern LSP.

The second spacer structure SP2 may include a second internal spacer ISP2, a second external spacer OSP2, and a second air gap AG2 between the second internal spacer ISP2 and the second external spacer OSP2.

The second internal spacer ISP2 may be adjacent to or in contact with the second side surface IS_S2 of the second line structure LS2. The second internal spacer ISP2 may include a portion disposed between the second air gap AG2 and the second side surface IS_S2 of the second line structure LS2, and a portion defining a lower portion of the second air gap AG2. The second internal spacer ISP2 may include a first portion ISP2a exposed by the second air gap AG2 and a second portion ISP2b extending upward from the first portion ISP2a.

Each of the first and second external spacers OSP1 and OSP2 may further include a lower portion OSP_L disposed at a lower level than a lower end of the air gap AG.

In each of the spacer structures SP, the internal spacer ISP may include the first and second internal spacers ISP1 and ISP2, the external spacer OSP may include the first and second external spacers OSP1 and OSP2, and the air gap AG may include the first and second air gaps AG1 and AG2.

In each of the spacer structures SP, at least one of the internal spacer ISP and the external spacer OSP may include regions ISP_O and OSP_O exposed by the air gap AG. Here, the regions ISP_O and OSP_O exposed by the air gap AG may include or may be formed of an oxide. For example, in each of the spacer structures SP, the internal spacer ISP exposed by the air gap AG may include a first internal region ISP_O including a first oxide, and the external spacer OSP exposed by the air gap AG may include a first external region OSP_O including a second oxide. The first and second oxides may be the same material, for example, SiON or SiOCN. The first and second oxides may be different materials, and, for example, one of the first and second oxides may be SiON, and the other thereof may be SiOCN. For example, the first oxide of the first internal region ISP_O of the internal spacer ISP may be SiOCN, and the second oxide of the first external region OSP_O of the external spacer OSP may be SiON.

The first internal region ISP_O and the first external region OSP_O exposed by the air gap AG may be oxidized regions. Hereinafter, the first internal region ISP_O will be described and referred to as an internal oxidized region, and the first external region OSP_O will be described and referred to as an external oxidized region.

In each of the spacer structures SP, at least one of the internal spacer ISP and the external spacer OSP may further include a region that does not include an oxide. For example, in each of the spacer structures SP, the internal spacer ISP may further include a second internal region ISP_N disposed adjacent to the internal oxidized region ISP_O, and the external spacer OSP may further include a second external region OSP_N disposed adjacent to the external oxidized region OSP_O.

The second internal region ISP_N may be an internal non-oxidized region, and the second external region OSP_N may be an external non-oxidized region. Hereinafter, the second internal region ISP_N will be described and referred to as an internal non-oxidized region, and the second external region OSP_N will be described and referred to as an external non-oxidized region.

The internal oxidized region ISP_O may be disposed between the air gap AG and the internal non-oxidized region ISP_N, and the external oxidized region OSP_O may be disposed between the air gap AG and the external non-oxidized region OSP_N. For example, in the first spacer structure SP1, the first portion ISP1a of the first internal spacer ISP1 may include a first internal oxidized region ISP_O exposed by the first air gap AG1. In the first spacer structure SP1, the first portion ISP1a of the first internal spacer ISP1 may further include a first internal non-oxidized region ISP_N disposed adjacent to the first internal oxidized region ISP_O. The first internal oxidized region ISP_O may be disposed between the first air gap AG1 and the first internal non-oxidized region ISP_N. In the first spacer structure SP1, the first external spacer OSP1 may include a first external oxidized region OSP_O exposed by the first air gap AG1. In the first spacer structure SP1, the first external spacer OSP1 may further include a first external non-oxidized region OSP_N disposed adjacent to the first external oxidized region OSP_O. The first external oxidized region OSP_O may be disposed between the first air gap AG1 and the first external non-oxidized region OSP_N.

The internal oxidized region ISP_O may include or may be formed of a SiOCN material layer formed by oxidizing a SiCN material layer. The internal non-oxidized region ISP_N may include the SiCN material layer. For example, the internal non-oxidized region ISP_N may include or may be formed of the SiCN material layer, and the internal oxidized region ISP_O may include or may be formed of the SiOCN material layer formed by oxidizing the SiCN material layer.

In order to improve the reliability and performance of the semiconductor device 1, the internal non-oxidized region ISP_N may include or may be formed of an SiCN material including silicon (Si) in an amount of about 25 at % to about 45 at %, carbon (C) in an amount of about 10 at % to about 40 at %, and nitrogen (N) in an amount of about 10 at % to about 40 at %.

In order to improve the reliability and performance of the semiconductor device 1, the internal oxidized region ISP_O may include or may be formed of a SiOCN material including oxygen (O) in an amount selected from a range of about 20 at % to about 50 at %. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

As illustrated in FIG. 4, an oxygen concentration of the internal oxidized region ISP_O may have a concentration gradient in which the concentration increases as it progresses in a third direction D1. The thirddirection D1 may be perpendicular to a surface of the internal spacer ISP exposed by the air gap AG and may be a direction from the internal spacer ISP to the air gap AG. The oxygen concentration of the internal oxidized region ISP_O may have a concentration gradient in which the concentration decreases as a distance from the air gap AG increases away from the air gap AG.

As illustrated in FIG. 4, the carbon concentration of the internal oxidized region ISP_O may have a concentration gradient in which the concentration decreases as it progresses in the thirddirection D1. The carbon concentration of the internal oxidized region ISP_O may have a concentration gradient in which the concentration increases as a distance from the air gap AG increases away from the air gap AG.

The oxygen concentration in the external oxidized region OSP_O may have a concentration gradient in which the concentration increases as it progresses in a fourthdirection D2 toward the air gap AG. That is, the oxygen concentration in the external oxidized region OSP_O may have a concentration gradient in which the concentration decreases as a distance from the air gap AG increases away from the air gap AG.

As one example, a material of the external oxidized region OSP_O may be different from a material of the internal oxidized region ISP_O. For example, the internal oxidized region ISP_O may include or may be formed of a SiOCN material formed by oxidizing a SiCN material, and the external oxidized region OSP_O may include or may be formed of a SiON material formed by oxidizing a SiN material. The internal non-oxidized region ISP_N may include or may be formed of the SiCN material, and the external non-oxidized region OSP_N may include or may be formed of the SiN material.

As another example, the external oxidized region OSP_O may include or may be formed of the same material as the material of the internal oxidized region ISP_O. For example, the internal oxidized region ISP_O and the external oxidized region OSP_O may include or may be formed of the SiOCN material formed by oxidizing the SiCN material.

As another example, the external non-oxidized region OSP_N may include at least two material layers, for example, a SiCN material layer adjacent to or in contact with the external oxidized region OSP_O and a SiN material layer in contact with the SiCN material layer and spaced apart from the external oxidized region OSP_O.

In order to improve the reliability and performance of the semiconductor device 1 and increase the degree of integration, the internal spacer ISP may have a first thickness t1, the air gap AG may have a first width t2, and the external spacer OSP may have a second thickness t3.

The first thickness t1 of the internal spacer ISP may range from about 5 Å to about 30 Å.

The first thickness t1 of the internal spacer ISP may range from about 7 Å to about 25 Å.

The first width t2 of the air gap AG may be greater than the first thickness t1 of the internal spacer ISP.

The second thickness t3 of the external spacer OSP may be greater than the first thickness t1 of the internal spacer ISP.

The second thickness t3 of the external spacer OSP may be greater than the first width t2 of the air gap AG.

The first width t2 of the air gap AG may be greater than the first thickness t1 of the internal spacer ISP, and may be less than about three times the first thickness t1 of the internal spacer ISP. The first width t2 of the air gap AG may be greater than the first thickness t1 of the internal spacer ISP, and may be less than about 1.5 times the first thickness t1 of the internal spacer ISP.

The second thickness t3 of the external spacer OSP may be greater than the first thickness t1 of the internal spacer ISP, and may be less than about three times the first thickness t1 of the internal spacer ISP. The second thickness t3 of the external spacer OSP may be greater than the first thickness t1 of the internal spacer ISP, and may be less than about twice the first thickness t1 of the inner spacer ISP.

The semiconductor device 1 may further include a contact structure CNT and insulating fences 55 (see FIG. 1).

The contact structure CNT may include a lower portion 59 and an upper portion 66 on the lower portion 59. In the contact structure CNT, the lower portion 59 may include a plug pattern. For example, the lower portion 59 may be the plug pattern including a first conductive pattern 60 and a second conductive pattern 63 on the first conductive pattern 60. The first conductive pattern 60 may include or may be formed of doped polysilicon, for example, polysilicon having dopants of an N-type conductivity type. The first conductive pattern 60 may be referred to as a doped silicon pattern. The first conductive pattern 60 may be electrically connected to the first impurity region 12a. The second conductive pattern 63 may include a metal-semiconductor compound layer (e.g., a metal silicide layer). For example, the metal-semiconductor compound layer may include or may be formed of at least one of WSi, TiSi, TaSi, NiSi, and CoSi.

In the contact structure CNT, the upper portion 66 may include a pad pattern that is in contact with and electrically connected to the lower portion 59. The upper portion 66 may be a pad pattern including a barrier layer 66a and a pad layer 66b on the barrier layer 66a. The barrier layer 66a may be in contact with the second conductive pattern 63.

A material of the upper portion 66 may be different from a material of the plug pattern 59. In the upper portion 66, that is, in the pad pattern, the barrier layer 66a may include or may be formed of at least one of TiN, TaN, WN, TiSiN, TaSiN, and RuTiN, and the pad layer 66b may include or may be formed of a metal material such as W. The second conductive pattern 63 may be disposed at a lower level than the upper end of the air gap AG.

The insulating fences 55 (see FIG. 1) may be disposed between the line structures LS, and the lower portion 59 of the contact structure CNT, that is, the plug pattern, may be disposed between the insulating fences 55. The upper portion 66, i.e., the pad pattern, may cover a portion of the spacer structure SP, and may cover a portion of an upper surface of the insulating capping pattern 33.

Hereinafter, the lower portion 59 will be described and referred to as the plug pattern, and the upper portion 66 will be described and referred to as the pad pattern.

A plurality of contact structures CNT may be disposed. The pad patterns 66 of the contact structures CNT may vertically overlap the line structures LS. For example, among the pad patterns 66, the pad pattern that is disposed on the first line structure LS1 may be referred to as a first pad pattern 66P1, and the pad pattern that is disposed on the second line structure LS2 may be referred to as a second pad pattern 66P2. The first pad pattern 66P1 may vertically overlap the first line structure LS1, and the second pad pattern 66P2 may vertically overlap the second line structure LS2.

At least a portion of the first spacer structure SP1 may be disposed between the first side surface IS_S1 of the first line structure LS1 and the contact structure CNT. At least a portion of the second spacer structure SP2 may be disposed between the second side surface IS_S2 of the second line structure LS2 and the contact structure CNT.

The first internal spacer ISP1 may be adjacent to or in contact with the first side surface IS_S1 of the first line structure LS1, and the first external spacer OSP1 may be adjacent to or in contact with the contact structure CNT. The second internal spacer ISP2 may be adjacent to or in contact with the second side surface IS_S2 of the second line structure LS2, and the second external spacer OSP2 may be adjacent to or in contact with the contact structure CNT.

An upper surface of the plug pattern 59 may be disposed at a higher level than the upper surface of the bit lines BL. The upper end of the air gap AG may be disposed at a higher level than the upper surface of the plug pattern 59.

In the cross-sectional structures illustrated in FIGS. 2A and 2B, the contact structure CNT may have an upper surface disposed at a higher level than the second line structure LS2, and a portion of the contact structure CNT may vertically overlap the second line structure LS2 in a vertical direction (Z-direction). For example, a portion of the upper portion 66 may cover at least a portion of the upper surface of the second line structure LS2.

The semiconductor device 1 may further include an upper insulating spacer 50 and an insulating separation pattern 78.

In the cross-sectional structures illustrated in FIGS. 2A and 2B, the upper insulating spacer 50 may be disposed on the second spacer structure SP2 and may be disposed on a side surface of the upper region of the insulating capping pattern 33 of the second line structure LS2. The upper insulating spacer 50 may define an upper portion of the second air gap AG2 and cover an upper region of the second external spacer OSP2, and may be disposed between the upper portion 66 of the contact structure CNT and an upper region of the second line structure LS2.

The insulating separation pattern 78 may surround a side surface of the pad pattern 66 disposed at a higher level than the line structures LS in the pad pattern 66 of the contact structure CNT and extend downwardly. In the cross-sectional structure illustrated in FIGS. 2A and 2B, the insulating separation pattern 78 may be disposed on the first spacer structure SP1 and may be disposed at a level higher than the plug pattern 59 of the contact structure CNT.

The insulating separation pattern 78 may seal at least a portion of an upper portion of the air gap AG. For example, the insulating separation pattern 78 may seal an upper portion of the first air gap AG1 of the first spacer structure SP1. Accordingly, the insulating separation pattern 78 may define the upper portion of the first air gap AG1 of the first spacer structure SP1. In the cross-sectional structure illustrated in FIGS. 2A and 2B, a portion of the insulating separation pattern 78 may vertically overlap a portion of the first line structure LS1. The insulating separation pattern 78 may include or may be formed of an insulating material such as silicon nitride. An upper surface of the insulating separation pattern 78 may be coplanar with an upper surface of the upper portion 66 of the contact structure CNT.

The semiconductor device 1 may further include a protective layer 74. The protective layer 74 may serve to protect a surface of the pad pattern 66 of the contact structure CNT from an oxidation process.

The protective layer 74 may include or may be formed of at least one of silicon oxide, silicon oxynitride (SiON), and a silicon oxycarbonitride (SiOCN).

The protective layer 74 may include an oxidized region in contact with the insulating separation pattern 78 and a non-oxidized region in contact with the pad pattern 66. For example, in the protective layer 74, the oxidized region in contact with the insulating separation pattern 78 may include or may be formed of SiON or SiOCN, and the non-oxidized region in contact with the pad pattern 66 may include or may be formed of SiN or SiCN.

At least a portion of the protective layer 74 may be disposed between the pad pattern 66 and the insulating separation pattern 78. For example, in the cross-sectional structure illustrated in FIG. 2B, based on the insulating separation pattern 78 disposed on the first spacer structure SP1, the protective layer 74 may include a first protective portion 74b disposed on a first side surface of the insulating separation pattern 78 in the third direction D1 from the lower portion 59 of the contact structure CNT to the second line structure LS2, and a second protective portion 74a disposed on a second side surface of the insulating separation pattern 78 in the fourth direction D2 from the lower portion 59 of the contact structure CNT to the first line structure LS1.

In the cross-sectional structure as illustrated in FIG. 2B, the first protective portion 74b of the protective layer 74 may have a lower end disposed at a lower level than a lower end of the insulating separation pattern 78, and the second protective portion 74a of the protective layer 74 may have a lower end disposed at a lower level than a center between an upper surface and a lower surface of the insulating separation pattern 78.

In the cross-sectional structure as illustrated in FIG. 3, the upper surface of the insulating capping pattern 33 may have a curved shape, and among the upper surface of the insulating capping pattern 33, the protruding portions 33c arranged sequentially in the second direction (Y-direction) may be alternately covered by the first protective portion 74b and the second protective portion 74a, and the first protective portion 74b and the second protective portion 74a may overlap each other in recessed portions between the protruding portions 33c. Accordingly, in the cross-sectional structure illustrated in FIG. 3, first portions of the protective layer 74 that are disposed on the protruding portions 33c may have a first thickness and second portions of the protective layer 74 that are disposed in the recessed portions may have a second thickness greater than the first thickness.

The semiconductor device 1 may further include an etching stop layer 80 and a data storage structure 90. The etching stop layer 80 may be disposed on the insulating separation pattern 78 and may include or may be formed of an insulating material.

As an example, the data storage structure 90 may be a capacitor that stores information in a dynamic random access memory (DRAM). For example, the data storage structure 90 may be a DRAM capacitor including a first electrode 82 penetrating through the etching stop layer 80 and electrically connected to the pad pattern 66, a dielectric layer 84 covering the first electrode 82 and the etching stop layer 80, and a second electrode 86 on the dielectric layer 84. The dielectric layer 84 may include or may be formed of a high-k dielectric material, silicon oxide, silicon nitride, silicon oxynitride, or a combination thereof.

As another example, the data storage structure 90 may be a structure for storing information on a memory different from the DRAM. For example, the data storage structure 90 may be a capacitor of a ferroelectric random access memory (FeRAM) including the first and second electrodes 82 and 86 and a dielectric layer 84 including a ferroelectric layer. For example, the dielectric layer 84 may include or may be a ferroelectric layer configured to record data using a polarization state.

In the above-described example embodiment, the spacer structures SP may reduce parasitic capacitance between adjacent conductive patterns. For example, one of the conductive patterns disposed adjacent to each other may be the plug pattern 59 of the contact structure CNT, and the other of the conductive patterns may be the first bit line BLa. Here, the first spacer structure SP1 may be disposed between the lower portion 59 of the contact structure CNT and the first bit line BLa.

In the first spacer structure SP1, because the first air gap AG1, the internal oxidized region ISP_O, and the external oxidized region OSP_O may serve to lower a dielectric constant of the first spacer structure SP1, the first spacer structure SP1 may reduce parasitic capacitance between the lower portion 59 of the contact structure CNT and the first bit line BLa.

The protective layer 74 may server to protect the surface of the pad pattern 66 of the contact structure CNT. For example, the protective layer 74 may server to protect the surface of the pad pattern 66 from the oxidation process for forming the internal oxidized region ISP_O and the external oxidized region OSP_O exposed by the air gap AG. Because the protective layer 74 may prevent the surface of the pad pattern 66 from being oxidized, the electrical characteristics of the pad pattern 66 may be prevented from being degraded due to the oxidization of the pad pattern 66.

Accordingly, the spacer structure SP and the protective layer 74 may improve the performance of the semiconductor device 1.

Hereinafter, various modified examples of the elements of the above-described embodiment will be described. Various modified examples of the elements of the example embodiment described below will be described focusing on the modified element or the replaced element. Furthermore, the modified or replaced elements described below are described with reference to the following drawings, but the modified or replaced elements may be combined with each other or combined with the above-mentioned elements, thus configuring a semiconductor device according to an example embodiment of the present disclosure.

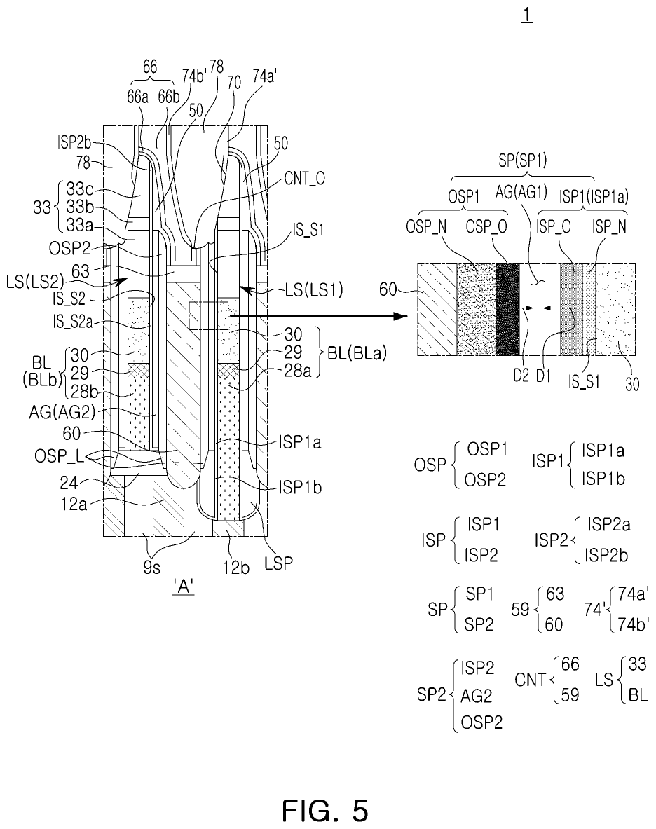

First, referring to FIG. 5, a modified example of the protective layer 74 in FIG. 2B will be described. FIG. 5 is a partially enlarged view which may correspond to FIG. 2B, and is a partially enlarged cross-sectional view illustrating a modified example of the protective layer 74 in the cross-sectional structure of FIG. 2B.

In a modified example, referring to FIG. 5, the first protective portion 74b of the protective layer 74 in FIG. 2B may be deformed into a first protective portion 74b′ that does not cover a portion of the pad pattern 66 disposed adjacent to the first spacer structure SP1. In FIG. 2B, the second protective portion 74a (see FIG. 2B) of the protective layer 74 having a lower end disposed at a lower level than the center between the upper surface and the lower surface of the insulating separation pattern 78 may be deformed into a second protective portion 74a′ having a lower end disposed at a higher level than the center between the upper surface and the lower surface of the insulating separation pattern 78. Accordingly, the protective layer 74 (see FIG. 2B) may be deformed into a protective layer 74′ including the first and second protective portions 74b′ and 74a′ as illustrated in FIG. 5.

The semiconductor device 1 may further include an oxide layer CNT_O disposed on the surface of the pad pattern 66 facing the insulating separation pattern 78 without being covered by the protective layer 74′. The oxide layer CNT_O may be disposed adjacent to an upper end of the first spacer structure SP1.

The contact structure CNT may include or may be formed of a first conductive material, and the oxide layer CNT_O may include or may be formed of an oxide of the first conductive material. For example, the oxide layer CNT_O may include or may be formed of an oxide formed by oxidizing a material of the barrier layer 66a. For example, when the barrier layer 66a is formed of TiN, the oxide layer CNT_O may include or may be formed of TiON.

In order to minimize an increase in resistance of the pad pattern 66 by the oxide layer CNT_O, the pad pattern 66 may have a first surface region covered by the protective layer 74′ and a second surface region covered by the oxide layer CNT_O, and the first surface region of the pad pattern 66 may be larger than the second surface region of the pad pattern 66. The protective layer 74′ may increase the productivity of the semiconductor device 1.

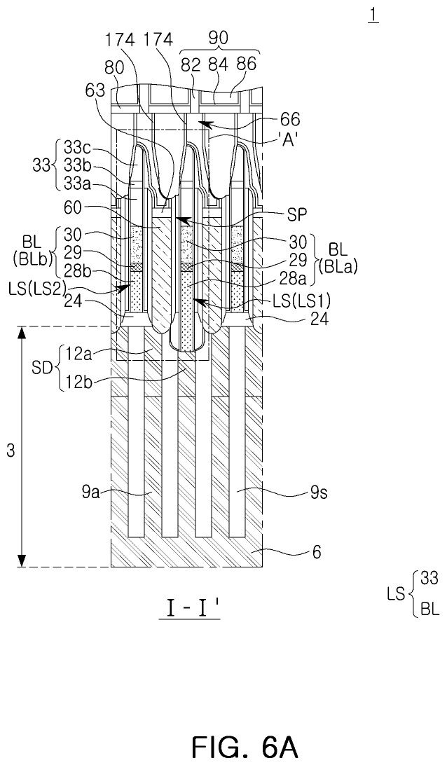

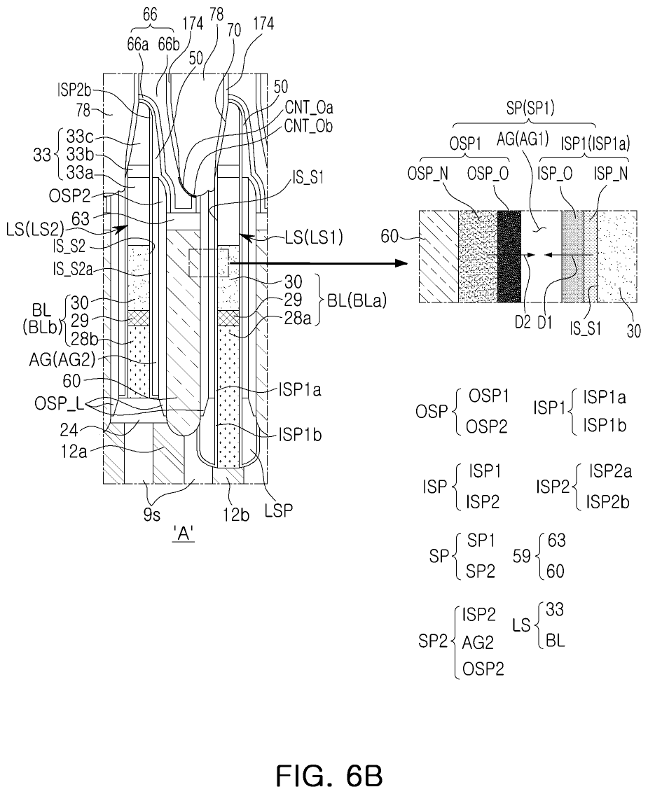

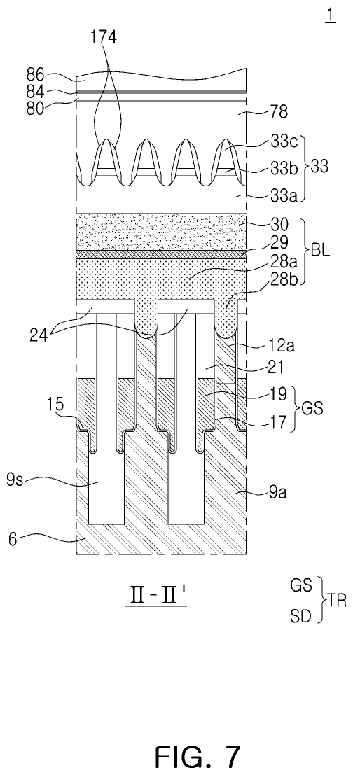

Next, referring to FIGS. 6A, 6B, and 7, a modified example of the protective layer 74 in FIG. 2B will be described. FIG. 6A is a conceptual cross-sectional view of a part taken along line I-I′ of FIG. 1 in order to describe a modified part in the cross-sectional structure of FIG. 2A, FIG. 6B is a partially enlarged view of a region indicated by part ‘A’ of FIG. 6A in order to describe a modified part in the cross-sectional structure of FIG. 2B, and FIG. 7 is a cross-sectional view conceptually illustrating a region taken along line II-II′ of FIG. 1 in order to describe a modified part in the cross-sectional structure of FIG. 3.

In a modified example, referring to FIGS. 6A, 6B, and 7, the protective layer 74 in FIGS. 2A and 2B may be deformed into a protective layer 174 configured to expose a portion of the pad pattern 66. For example, in the cross-sectional structure illustrated in FIG. 6B, the protective layer 174 may expose a portion of the pad pattern 66 disposed adjacent to the first spacer structure SP1, for example, a portion of the barrier layer 66a and a portion of the pad layer 66b. In the cross-sectional structure as illustrated in FIG. 7, the protective layer 174 may cover side surfaces of the protruding portions 33c sequentially arranged in the second direction (Y-direction) among a curved upper surface of the insulating capping pattern 33.

The semiconductor device 1 may further include oxide layers CNT_Oa and CNT_Ob disposed on the surface of the pad pattern 66 facing the insulating separation pattern 78 without being covered by the protective layer 174. The oxide layers CNT_Oa and CNT_Ob may be disposed adjacent to the upper end of the first spacer structure SP1. The oxide layers CNT_Oa and CNT_Ob may include a first oxide layer CNT_Oa formed by oxidizing a material of the pad layer 66b and a second oxide layer CNT_Ob formed by oxidizing a material of the barrier layer 66a. For example, when the pad layer 66b is formed of W, the first oxide layer CNT_Oa may include or may be formed of tungsten oxide, and when the barrier layer 66a is formed of TiN, the oxide layer CNT_O may include or may be formed of TiON. In order to minimize the increase in the resistance of the pad pattern 66 due to the oxide layers CNT_Oa and CNT_Ob, the pad pattern 66 may include a first surface region covered by the protective layer 174 and a second surface region covered by the oxide layers CNT_Oa and CNT_Ob, and the first surface region may be larger than the second surface region. The protective layer 174 may increase the productivity of the semiconductor device 1.

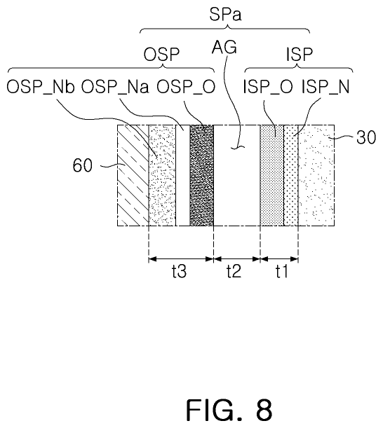

Next, various modified examples of the spacer structures SP described above will be described with reference to FIGS. 8, 9, and 10, respectively. FIGS. 8, 9, and 10 are partially enlarged cross-sectional views corresponding to an enlarged region based on the first spacer structure SP1 in FIG. 2B.

In the modified example, referring to FIG. 8, the spacer structure SP in FIGS. 2A and 2B may be deformed into a spacer structure SPa as in FIG. 8. For example, the external non-oxidized region OSP_N (see FIG. 2B) of the external spacer OSP (see FIG. 2B) of the spacer structure SP may be replaced with the first external non-oxidized region OSP_Na and the second external non-oxidized region OSP_Nb as illustrated in FIG. 8.

Accordingly, the external spacer OSP of the spacer structure SPa may include the external oxidized region OSP_O, the first external non-oxidized region OSP_Na in contact with the external oxidized region OSP_O, and the second external non-oxidized region OSP_Nb in contact with the first external non-oxidized region OSP_Na. The first external non-oxidized region OSP_Na may be disposed between the external oxidized region OSP_O and the second external non-oxidized region OSP_Nb.

The first external non-oxidized region OSP_Na and the second external non-oxidized region OSP_Nb may be different materials. For example, the first external non-oxidized region OSP_Na may include or may be formed of a SiCN material, and the second external non-oxidized region OSP_Nb may include or may be formed of a SiN material. The external oxidized region OSP_O may include or may be formed of a SiOCN material formed by oxidizing a SiCN material.

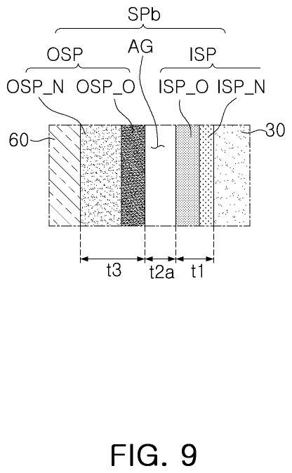

In the modified example, referring to FIG. 9, the air gap AG in FIG. 2B may be deformed into an air gap AG having a reduced width as in FIG. 9.

A width t2a of the air gap AG may be equal to or less than a thickness t1 of the internal spacer ISP. A thickness t3 of the external spacer OSP may be greater than the thickness t1 of the internal spacer ISP, and the thickness t3 of the external spacer OSP may be greater than the width t2a of the air gap AG. The width t2a of the air gap AG may be less than the thickness t1 of the internal spacer ISP, and may be greater than about 0.5 times the thickness t1 of the internal spacer ISP. Accordingly, the spacer structure SP in FIG. 2B may be deformed into a spacer structure SPb including the internal spacer ISP, the air gap AG having a reduced width, and the external spacer OSP.

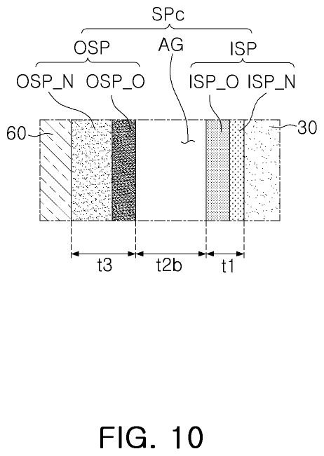

In the modified example, referring to FIG. 10, the air gap AG in FIG. 2B may be deformed into an air gap AG having an increased width as illustrated in FIG. 10. A width t2b of the air gap AG may be greater than the thickness t3 of the external spacer OSP, and the thickness t3 of the external spacer OSP may be greater than the thickness t1 of the internal spacer ISP. Accordingly, the spacer structure SP in FIG. 2B may be deformed into a spacer structure SPc including the internal spacer ISP, the air gap AG having an increased width, and the external spacer OSP.

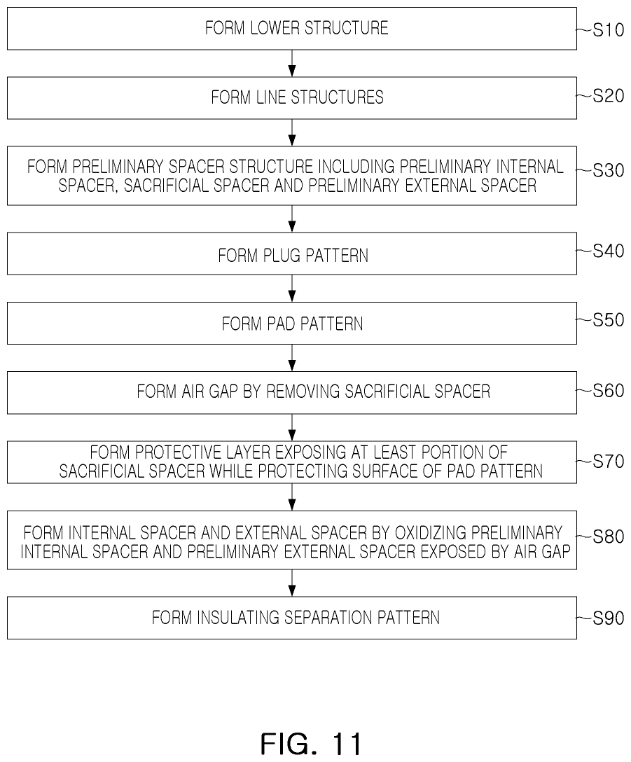

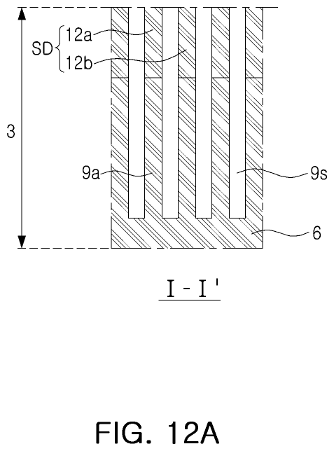

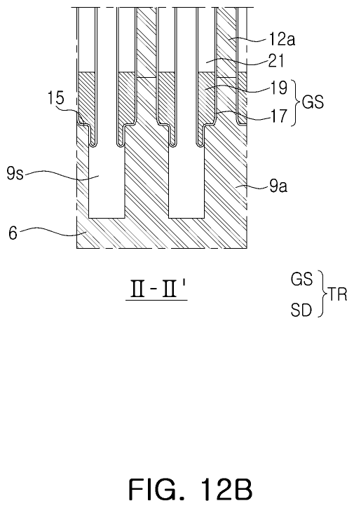

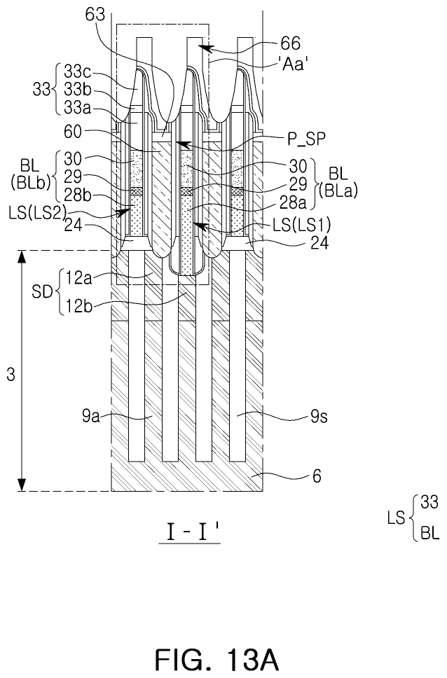

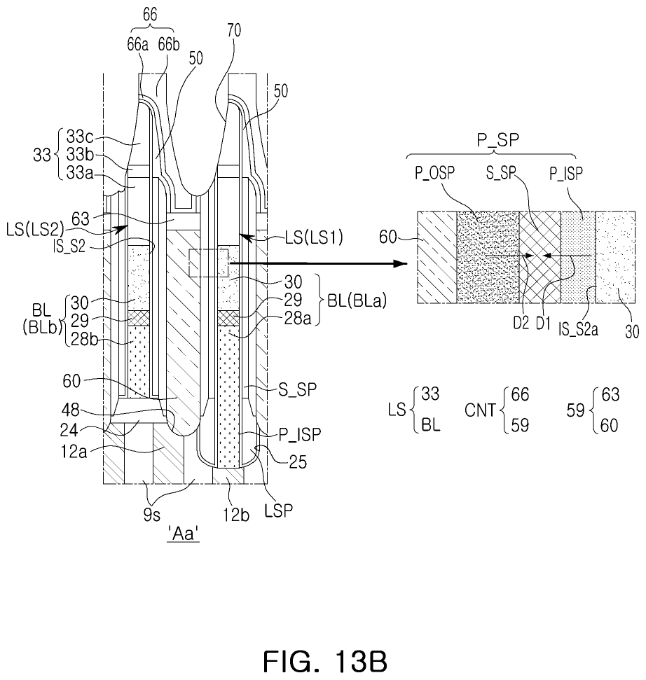

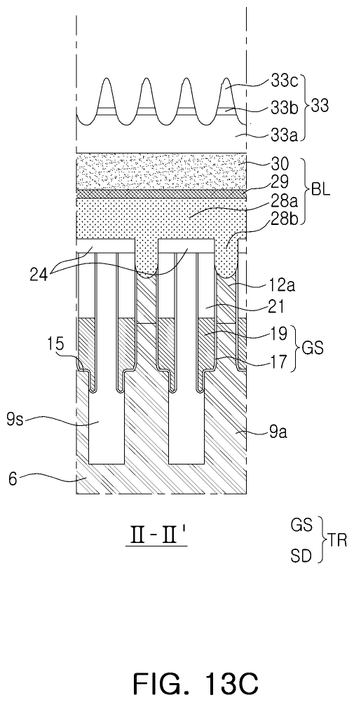

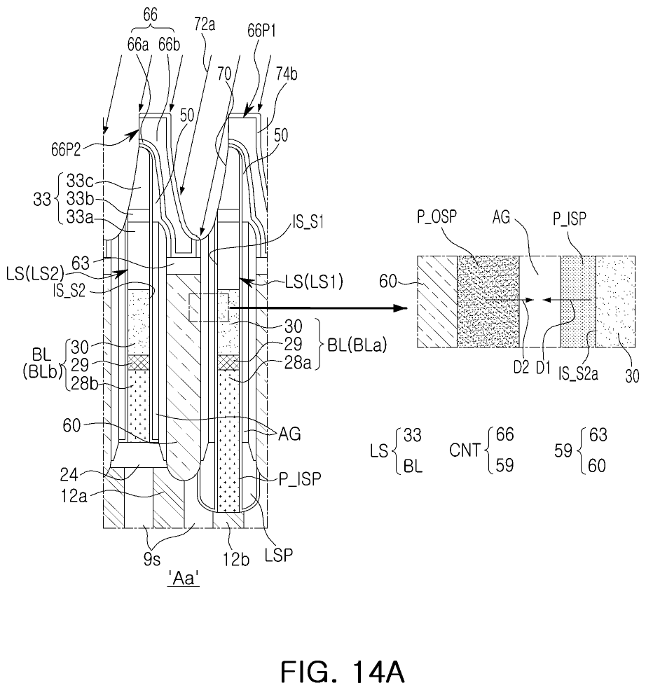

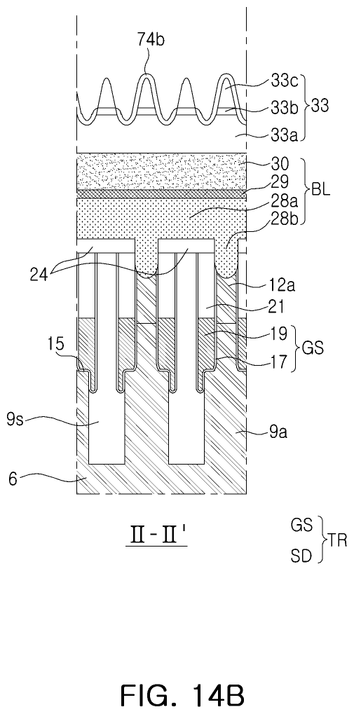

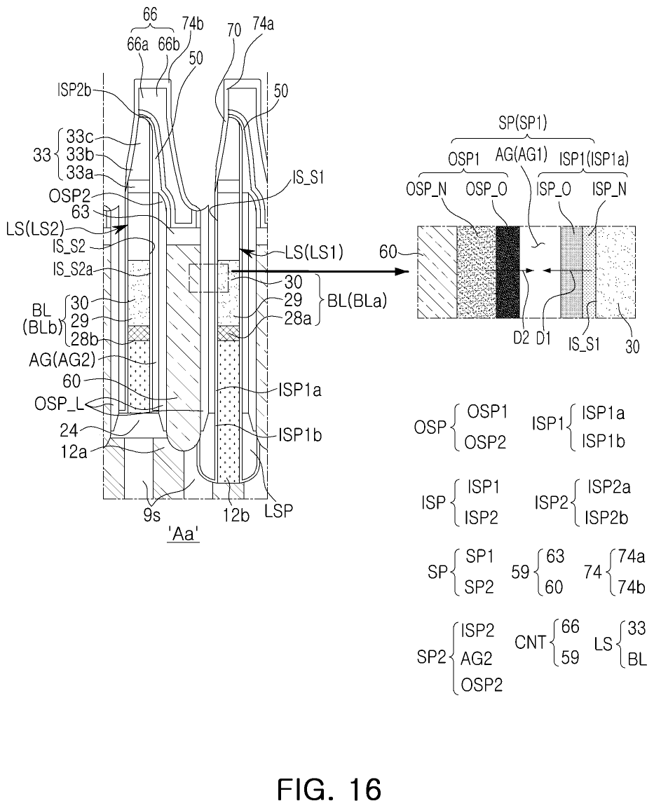

Next, referring to FIG. 1 and FIGS. 11 to 17, an exemplary example of a method for forming a semiconductor device according to an example embodiment of the present disclosure will be described. In FIGS. 11 to 17, FIG. 11 is a process flowchart schematically illustrating an exemplary exampling of the method for forming a semiconductor device according to an example embodiment of the present disclosure, FIGS. 12A and 13A are cross-sectional views conceptually illustrating a region taken along line I-I′ of FIG. 1, FIGS. 12B, 13C, 14B, and 15B are cross-sectional views conceptually illustrating regions taken along line II-II′ of FIG. 1, and FIGS. 13B, 14A, 15A, 16, and 17 are partially enlarged views conceptually illustrating a region indicated by region ‘Aa’ of FIG. 13A.

Referring to FIGS. 1, 11, 12A, and 12B, a lower structure 3 may be formed (S10). The forming of the lower structure 3 may include forming a device isolation region 9s disposed on the substrate 6 and defining the active region 9a. The substrate 6 may be a semiconductor substrate.

The device isolation region 9s may be formed by a shallow trench isolation process. The device isolation region 9s may include or may be formed of an insulating material such as silicon oxide and/or silicon nitride.

The forming of the lower structure 3 may further include forming a transistor TR on the substrate 6. The forming of the transistor TR may include forming a gate trench 15 that intersects the active region 9a and extends into the device isolation region 9s, and forming a gate structure GS and a gate capping layer 21 in the gate trench 15.

The gate structure GS may include a gate dielectric layer 17 conformally covering an internal wall of the gate trench 15, and a gate electrode 19 disposed on the gate dielectric layer 17 and partially filling the gate trench 15. The gate capping layer 21 may be disposed on the gate electrode 19 and may fill the remaining portion of the gate trench 15. The gate capping layer 21 may include or may be formed of an insulating material, for example, silicon nitride.

The forming of the transistor TR may further include forming first and second impurity regions 12a and 12b by an ion implantation process in the active region 9a. The first and second impurity regions 12a and 12b may be source/drain regions SD.

As an example, the first and second impurity regions 12a and 12b may be formed by injecting impurities into the active region 9a before forming the device isolation region 9s.

As another example, the first and second impurity regions 12a and 12b may be formed before forming the gate trench 15 after forming the device isolation region 9s.

As yet another example, the first and second impurity regions 12a and 12b may be formed after forming the gate structure GS and the gate capping layer 21.

The active region 9a may have dopants of a P-type conductive type, and the first and second impurity regions 12a and 12b may have dopants of an N-type conductive type.

Referring to FIGS. 1, 11, 13A, 13B, and 13C, line structures LS may be formed (S20). The forming of the line structures LS may include forming a buffer pattern 24 on the lower structure 3, forming an opening 25 penetrating through the buffer pattern 24 and exposing the second impurity region 12b, and forming line structures LS including a portion disposed on the buffer pattern 24 and a portion passing through the opening 25 and electrically connected to the second impurity region 12b. Among the line structures LS, a portion passing through the opening 25 may be spaced apart from a side surface of the opening 25 in a cross-sectional structure as illustrated in FIG. 13B.

Each of the line structures LS may include a conductive pattern BL and an insulating capping pattern 33 on the conductive pattern BL. The line structures LS may include a first line structure LS1 and a second line structure LS2 disposed adjacent to each other.

A preliminary inner spacer P_ISP covering the side surface of each of the line structures LS and covering the side surface of the opening 25 may be conformally formed, a lower spacer pattern LSP filling the opening 25 is formed on the preliminary inner spacer P_ISP, a preliminary sacrificial spacer layer may be conformally formed, and the preliminary sacrificial spacer layer may be anisotropically etched to form a sacrificial spacer S_SP remaining on the side surfaces of each of the line structures LS.

A preliminary external spacer layer may be conformally formed on the line structures LS and the sacrificial spacer S_SP, and the preliminary external spacer layer may be anisotropically etched to form a preliminary external spacer P_OSP. The preliminary internal spacer P_ISP, the sacrificial spacer S_SP, and the preliminary external spacer P_OSP may constitute preliminary spacer structures P_SP. Accordingly, the preliminary spacer structures P_SP including the preliminary internal spacer P_ISP, the sacrificial spacer S_SP, and the preliminary external spacer P_OSP may be formed (S30).

The preliminary internal spacer P_ISP may include or may be formed of silicon nitride or silicon carbonitride (SiCN). The preliminary external spacer P_OSP may include or may be formed of at least one of silicon nitride and silicon carbonitride (SiCN). The preliminary external spacer P_OSP may be formed in a single layer or multiple layers.

The sacrificial spacer S_SP may include or may be formed of a material different from a material of the preliminary internal spacer P_ISP and a material of the preliminary external spacer P_OSP. The sacrificial spacer S_SP may include or may be formed of a material having etching selectivity with respect to the material of the preliminary internal spacer P_ISP and the material of the preliminary external spacer P_OSP. For example, the sacrificial spacer S_SP may include or may be formed of silicon oxide or a low-κ dielectric material. Here, the low-κdielectric material may be a dielectric material having a dielectric constant smaller than that of the silicon oxide.

The line structures LS may be parallel to each other, and each of the line structures LS may extend in the second direction (Y-direction). The insulating fences 55 (see FIG. 1) may be formed between the line structures LS.

A plug pattern 59 may be formed (S40). The plug pattern 59 may be formed between the line structures LS and between the insulating fences 55 (see FIG. 1).

The forming of the plug pattern 59 may include forming a contact opening 48 extending downward by passing through the insulating fences 55 and exposing the first impurity region 12a, forming a first conductive pattern 60 partially filling the contact opening 48, and forming a second conductive pattern 63 on the first conductive pattern 60. The first conductive pattern 60 may include or may be formed of doped silicon, and the second conductive pattern 63 may include or may be formed of a metal-semiconductor compound (e.g., metal silicide).

During the formation of the plug pattern 59, upper ends of the sacrificial spacer S_SP and the preliminary external spacer P_OSP may be lowered. For example, the upper ends of the sacrificial spacer S_SP and the preliminary external spacer P_OSP may be disposed at a higher level than the upper surface of the plug pattern 59 and may be disposed at a lower level than the upper surfaces of the line structures LS.

Upper insulating spacers 50 covering a side surface of the contact opening 48 may be formed on the plug pattern 59. The upper insulating spacers 50 may cover the sacrificial spacer S_SP and the preliminary external spacer P_OSP disposed at a higher level than the plug pattern 59, and side surfaces of the line structures LS.

A pad pattern 66 may be formed (S50). The forming of the pad pattern 66 may include forming a barrier layer 66a covering the plug pattern 59 and the line structures LS, forming a pad layer 66b on the barrier layer 66a, and forming a trench 70 by patterning the pad layer 66b and the barrier layer 66a. The trench 70 may be referred to as a separate trench, a recess, or a groove.

The trench 70 may extend downwardly by penetrating through the pad layer 66b and the barrier layer 66a disposed at a higher level than the line structures LS, and expose a sacrificial spacer S_SP disposed adjacent to any one of a pair of line structures LS adjacent to each other. For example, between the first line structure LS1 and the second line structure LS2 disposed adjacent to each other among the line structures LS, the sacrificial spacer S_SP disposed adjacent to the first line structure LS1 may be exposed by the trench 70, and the sacrificial spacer S_SP disposed adjacent to the second line structure LS2 may not be exposed by the trench 70 and may be covered by the upper insulating spacer 50.

The plug pattern 59 and the pad pattern 66 may constitute a contact structure CNT. A plurality of contact structures CNT may be disposed. The pad patterns 66 of the contact structures CNTs may vertically overlap the line structures LS. For example, among the pad patterns 66, a pad pattern that is disposed on the first line structure LS1 may be referred to as a first pad pattern 66P1, and a pad pattern that is disposed on the second line structure LS2 may be referred to as a second pad pattern 66P2.

Referring to FIGS. 1, 11, 14A, and 14B, the sacrificial spacer S_SP may be removed to form an air gap AG (S60). A portion of the air gap AG may be exposed by the trench 70.

A first directional deposition process 72a (e.g., a sputtering process) may be performed to form a first protective portion 74b on a sidewall of the trench 70 in a first diagonal direction. The first directional deposition process 72a may be a deposition process of forming the first protective portion 74b on a partial side surface of the trench 70 so that the air gap AG exposed by the trench 70 is not sealed between the pad patterns 66 arranged in the first direction (X-direction). For example, ions for forming the first protective portion 74b may travel along a straight line extending in a first inclined direction with respect to the upper surface of the lower structure 3 to form the first protective portion 74b, and after the first protective portion 74b is formed, the upper portion of the air gap AG may be opened between the pad patterns 66 arranged in the first direction (X-direction).

Referring to FIGS. 1, 11, 15A, and 15B, a second directional deposition process 72b may be advanced to form a second protective portion 74a on a sidewall of the trench 70 in a second diagonal direction. The second directional deposition process 72b may be a deposition process of forming the second protective portion 74a on a partial side surface of the trench 70 so that the air gap AG exposed by the trench 70 is not sealed between the pad patterns 66 arranged in the first direction (X-direction). For example, ions for forming the second protective portion 74a may travel along a straight line extending in a second inclined direction with respect to the upper surface of the lower structure 3 to form the second protective portion 74a, and after the second protection portion 74a is formed, the upper portion of the air gap AG may be opened between the pad patterns 66 arranged in the first direction (X-direction).

Accordingly, the first and second protective portions 74b and 74a may be formed on side surfaces of the trench 70 so as to prevent the air gap AG exposed by the trench 70 from being sealed between the pad patterns 66 arranged in the first direction (X-direction) by the first and second directional deposition processes 72a and 72b performed in different first and second inclined directions, and the first and second protective portions 74b and 74a may cover exposed surfaces of the pad patterns 66P1 and 66P2. In some embodiments, at least one of the first and second directional deposition processes 72a and 72b may be performed during a time when a resulting structure of FIG. 13A is rotating. The first and second protective portions 74b and 74a may constitute a protective layer 74. Accordingly, the protective layer 74 may be formed to protect the surface of the pad pattern 66 and expose at least a portion of the air gap AG (S70).

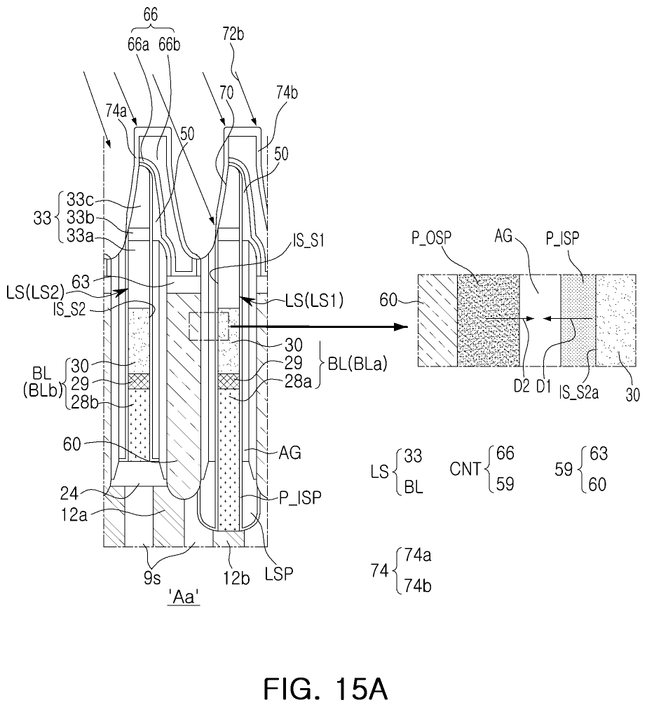

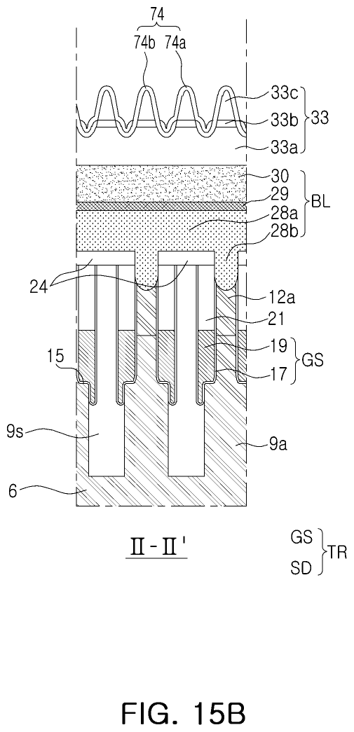

Referring to FIGS. 1, 11, and 16, the preliminary internal spacer P_ISP (see FIG. 15A) and the preliminary external spacer P_OSP (see FIG. 15A) exposed by the air gap AG may be oxidized to form the internal spacer ISP and the external spacer OSP. During an oxidation process of oxidizing the preliminary internal spacer P_ISP (see FIG. 15A) and the preliminary external spacer P_OSP (see FIG. 15A) exposed by the air gap AG, the surface of the pad pattern 66 may be protected by the protective layer 74.

In an example embodiment, the internal spacer ISP, the air gap AG, and the external spacer OSP may constitute the spacer structures SP as described in FIGS. 2A and 2B. For example, the internal spacer ISP may include the internal oxidized region ISP_O and the internal non-oxidized region ISP_N as described in FIG. 2B, and the external spacer OSP may include the external oxidized region OSP_O and the external non-oxidized region OSP_N as described in FIG. 2B. Accordingly, because the spacer structures SP are described in FIGS. 2A and 2B, a detailed description thereof will be omitted.

In a modified example, the internal spacer ISP, the air gap AG, and the external spacer OSP may form the spacer structure SPa (see FIG. 8) as described in FIG. 8.

In a modified example, the internal spacer ISP, the air gap AG, and the external spacer OSP may form the spacer structure SPb (see FIG. 9) as described in FIG. 9.

In a modified example, the internal spacer ISP, the air gap AG, and the external spacer OSP may form the spacer structure SPc (see FIG. 10) as described in FIG. 10.

In a modified example, in order to increase the productivity of the semiconductor device 1, the protective layer 74 may be deformed into a protective layer 74′ as illustrated in FIG. 5 that exposes a portion of the pad pattern 66. During the oxidation process of oxidizing the preliminary internal spacer P_ISP (see FIG. 15A) and the preliminary external spacer P_OSP (see FIG. 15A) exposed by the air gap AG, a portion of the pad pattern 66 exposed by the protective layer 74′ of FIG. 5 may be oxidized and formed of the oxide layer CNT_O (see FIG. 5) as described in FIG. 5.

In a modified example, in order to increase the productivity of the semiconductor device 1, the protective layer 74 may be deformed into the protective layer 174 as illustrated in FIGS. 6A and 6B that exposes a portion of the pad pattern 66. During the oxidation process of oxidizing the preliminary internal spacer P_ISP (see FIG. 15A) and the preliminary external spacer P_OSP (see FIG. 15A) exposed by the air gap AG, a portion of the pad pattern 66 exposed by the protective layer 174 (see FIG. 6B) may be oxidized to form the oxide layers CNT_Oa and CNT_Ob (see FIG. 6B) as described in FIGS. 6A and 6B.

Referring to FIGS. 1, 11, and 17, an insulating separation pattern 78 may be formed (S90). The insulating separation pattern 78 may seal the upper portion of the air gap AG while filling the trench 70 in which a portion of the side wall is covered by the protective layer 74. The forming of the insulating separation pattern 78 may include forming an insulating material layer, and planarizing the insulating material layer to expose the upper surface of the pad pattern 66.

In a modified example, after performing the oxidation process of oxidizing the preliminary internal spacer P_ISP (see FIG. 15A) and the preliminary external spacer P_OSP (see FIG. 15A) exposed by the air gap AG, the protective layer 74 may be removed and after removing the protective layer 74, the insulating separation pattern 78 may be formed.

Again, referring to FIGS. 1, 2A, 2B, 3, and 4, the etching stop layer 80 and the data storage structure 90 may be sequentially formed. The etching stop layer 80 may cover the insulating separation pattern 78 and the pad pattern 66. When the data storage structure 90 is a capacitor for storing information in the DRAM, the data storage structure 90 may include the first electrode 82 penetrating through the etching stop layer 80 and electrically connected to the pad pattern 66, the dielectric layer 84 covering the first electrode 82 and the etching stop layer 80, and the second electrode 86 on the dielectric layer 84.

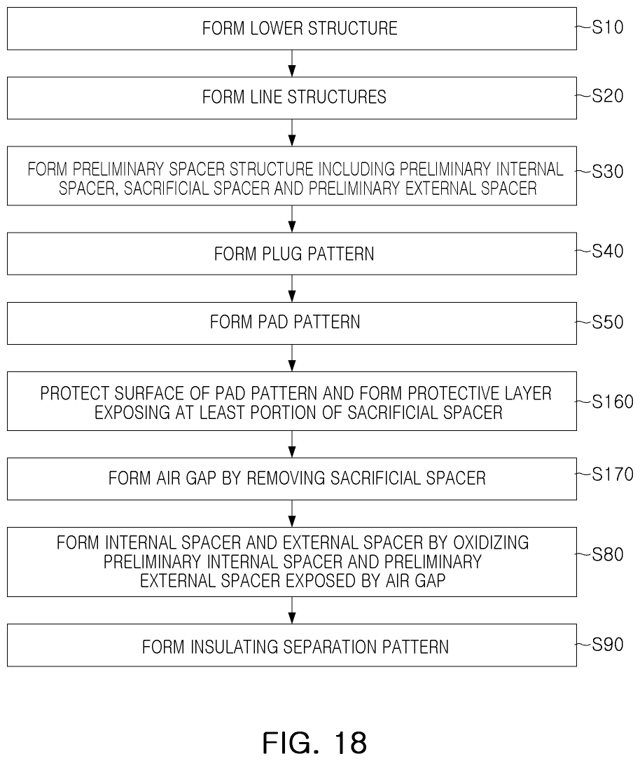

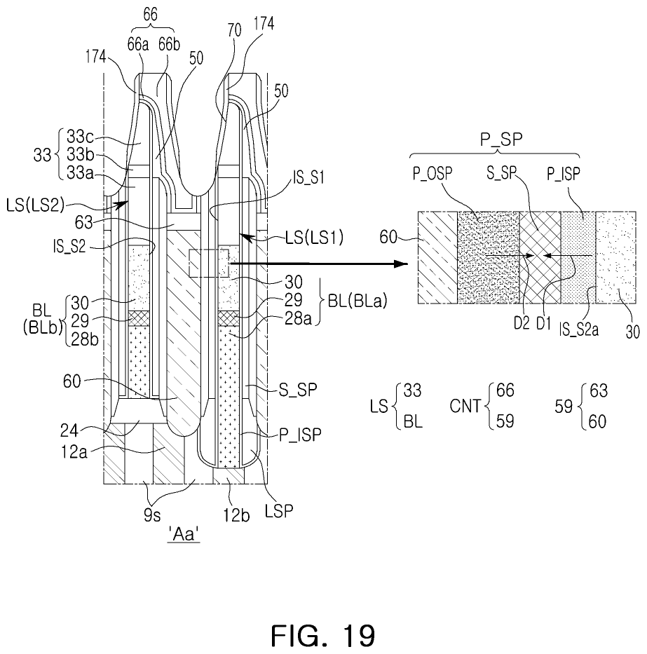

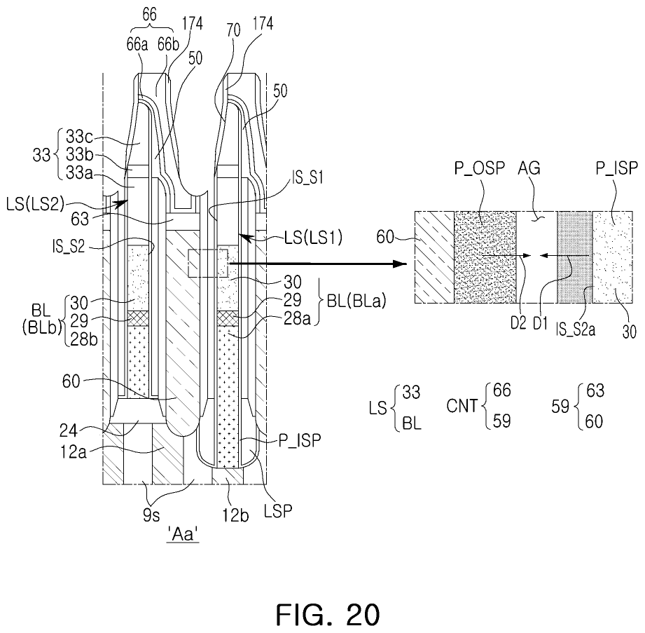

Next, referring to FIGS. 1 and 18 to 20, a modified example of a method for forming a semiconductor device according to an example embodiment of the present disclosure will be described. In FIGS. 18 to 20, FIG. 18 is a process flowchart schematically illustrating a modified example of a method of forming a semiconductor device according to an example embodiment of the present disclosure, and FIGS. 19 and 20 are partially enlarged views conceptually illustrating a region indicated by part ‘Aa’ of FIG. 13A.

Referring to FIGS. 1, 18, and 19, the trench 70 and the contact structure CNT described in FIGS. 13A, 13B and 13C may be formed by performing the method described in FIGS. 11, 12A, 12B, 13A, 13B and 13C. As described above, the contact structure CNT may include the plug pattern 59 and the pad pattern 66.

The protective layer 174 configured to protect the surface of the pad pattern 66 and expose at least a portion of the sacrificial spacer S_SP may be formed (S160). The forming of the protective layer 174 may include forming a material layer conformally covering an internal wall of the trench 70 and an upper surface of the pad pattern 66, and anisotropically etching the material layer. The protective layer 174 may expose a portion of the surface of the pad pattern 66 while exposing at least a portion of the sacrificial spacer S_SP.

Referring to FIGS. 1, 18, and 20, the sacrificial spacer S_SP (see FIG. 19) may be removed to form the air gap AG (S170). The removal of the sacrificial spacer S_SP (see FIG. 19) to form the air gap AG may be performed after forming the protection layer 174.

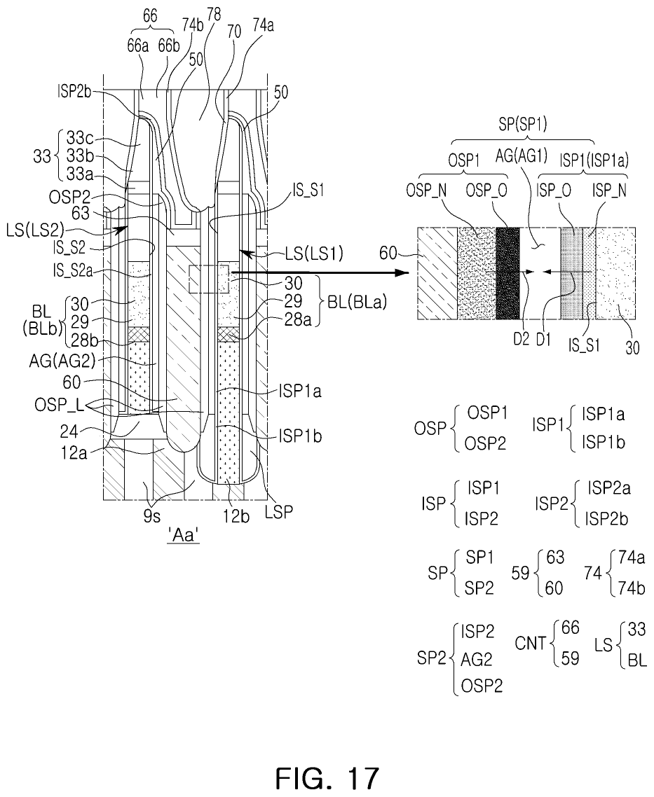

Referring to FIGS. 6A and 6B along with FIGS. 1 and 18, the preliminary internal spacer P_ISP (see FIG. 20) and the preliminary external spacer P_OSP (see FIG. 20) exposed by the air gap AG may be oxidized to form the internal spacer ISP and the external spacer OSP in the same manner as described in FIGS. 11 and 17 (S80). The insulating separation pattern 78 may be formed in the same manner as illustrated in FIGS. 11 and 17 (S90). Then, the etching stop layer 80 and the data storage structure 90 may be sequentially formed.

During the oxidation process of oxidizing the preliminary internal spacer P_ISP (see FIG. 20) and the preliminary external spacer P_OSP (see FIG. 20) exposed by the air gap AG, a portion of the pad pattern 66 exposed by the protective layer 174 (see FIG. 20) may be oxidized to form the oxide layers CNT_Oa and CNT_Ob (see FIG. 6B), as described in FIGS. 6A and 6B.

According to example embodiments, there may be provided a semiconductor device including a spacer structure configured to reduce parasitic capacitance between adjacent conductive patterns. The spacer structure may include an air gap and an oxidized region exposed by the air gap. In the spacer structure disposed between the adjacent conductive patterns, the air gap and the oxidized region may serve to lower a dielectric constant of the spacer structure, thereby reducing parasitic capacitance between the conductive patterns.

One of the conductive patterns may be a contact structure including a pad pattern. A protective layer may be disposed to protect a surface of the pad pattern from an oxidation process for forming the oxidized region of the spacer structure. Because the protective layer may prevent oxidization of the surface of the pad pattern, electrical characteristics of the pad pattern may be prevented from being degraded due to the oxidization of the pad pattern. Accordingly, the protective layer may improve the performance of the semiconductor device.

The spacer structure and the protective layer may improve the performance of the semiconductor device.

The various and beneficial advantages and effects of example embodiments are not limited to the above description, and will be more easily understood in the course of describing specific example embodiments.

Although example embodiments of the present disclosure have been described with reference to the accompanying drawings, it will be understood by those skilled in the art that the present disclosure may be implemented in other specific forms without changing its technical concepts or essential features. Therefore, it should be understood that the example embodiments described above are exemplary and not limited in all respects.

What is claimed is:

1. A semiconductor device comprising:
a first line structure and a second line structure extending parallel with each other;
a plurality of spacer structures, wherein each of the plurality of spacer structures is disposed on a corresponding side surface of side surfaces of the first and second line structures;
a contact structure including a lower portion disposed between the first line structure and the second line structure and an upper portion on the lower portion;
an insulating separation pattern on a side surface of the upper portion of the contact structure; and
a protective layer including a first protective portion disposed between the insulating separation pattern and the upper portion of the contact structure,
wherein the plurality of spacer structures include a first spacer structure on a first side surface of the first line structure and a second spacer structure on a second side surface of the second line structure,
wherein the first side surface of the first line structure and the second side surface of the second line structure face each other,
wherein at least a portion of the first spacer structure is disposed between the first side surface of the first line structure and the lower portion of the contact structure,
wherein at least a portion of the second spacer structure is disposed between the second side surface of the second line structure and the lower portion of the contact structure,
wherein the first spacer structure includes:
an internal spacer contacting the first side surface of the first line structure;
an external spacer spaced apart from the first side surface of the first line structure; and
an air gap between the internal spacer and the external spacer,
wherein the internal spacer includes a first region having an oxide and the external spacer includes a second region having an oxide, and
wherein the air gap is disposed between the first region and the second region.

2. The semiconductor device of claim 1,
wherein each of the first and second line structures includes a conductive pattern and an insulating capping pattern on the conductive pattern.

3. The semiconductor device of claim 2,
wherein the lower portion of the contact structure includes a plug pattern,
wherein the upper portion of the contact structure includes a pad pattern contacting the plug pattern, and
wherein a material of the plug pattern is different from a material of the pad pattern.

4. The semiconductor device of claim 3,
wherein the plug pattern includes a doped silicon pattern and a metal-semiconductor compound layer on the doped silicon pattern, and
wherein the pad pattern includes a barrier layer and a pad layer on the barrier layer.

5. The semiconductor device of claim 3,
wherein an upper surface of the plug pattern is disposed at a higher level than an upper surface of the conductive pattern.

6. The semiconductor device of claim 3,
wherein an upper surface of the pad pattern is at a higher level than an upper surface of the insulating capping pattern, and
wherein a lower surface of the pad pattern is at a lower level than the upper surface of the insulating capping pattern.

7. The semiconductor device of claim 1,
wherein a portion of the upper portion of the contact structure vertically overlaps at least a portion of the second line structure.

8. The semiconductor device of claim 1,
wherein at least one of the first region of the internal spacer and the second region of the external spacer includes a SiOCN material.

9. The semiconductor device of claim 8,
wherein a carbon concentration of the at least one of the first and second regions has a concentration gradient in which the carbon concentration increases as a distance from the air gap increases away from the air gap.

10. The semiconductor device of claim 1,
wherein one of the first and second regions includes a SiOCN material, and
wherein the other of the first and second regions includes a SiON material.

11. The semiconductor device of claim 1,
wherein the first region of the internal spacer includes a SiOCN material, and
wherein the second region of the external spacer includes a SiON material.

12. The semiconductor device of claim 1, further comprising:
an oxide layer between the insulating separation pattern and the upper portion of the contact structure,
wherein the upper portion of the contact structure includes a first portion contacting the protective layer and a second portion contacting the oxide layer.

13. The semiconductor device of claim 12,
wherein the contact structure includes a first conductive material, and
wherein the oxide layer includes an oxide of the first conductive material.

14. The semiconductor device of claim 1,
wherein the protective layer includes at least one of silicon oxide, SiON, and SiOCN.

15. The semiconductor device of claim 1, further comprising:
a data storage structure electrically connected to the contact structure and on the contact structure.

16. A semiconductor device comprising:
a lower structure;
a line structure disposed on the lower structure and including a conductive pattern and an insulating capping pattern on the conductive pattern;
a contact structure including a lower portion disposed adjacent to a side surface of the line structure and an upper portion disposed on the lower portion and disposed at a higher level than an upper surface of the line structure;
a spacer structure between a side surface of the lower portion of the contact structure and the side surface of the line structure;
an insulating separation pattern on the spacer structure; and
a protective layer between the upper portion of the contact structure and the insulating separation pattern,
wherein the spacer structure includes:
an internal spacer;
an external spacer; and
an air gap between the internal spacer and the external spacer,
wherein regions of the internal spacer and the external spacer exposed by the air gap include an oxide, and
wherein the insulating separation pattern seals at least a portion of an upper portion of the air gap.

17. The semiconductor device of claim 16,
wherein at least one of the internal spacer and the external spacer includes a first region including the oxide and a second region including nitride or carbonitride,
wherein the oxide includes oxynitride or oxycarbonitride, and
wherein the first region is disposed between the air gap and the second region.

18. The semiconductor device of claim 16,
wherein a thickness of the external spacer is greater than a thickness of the internal spacer.

19. A semiconductor device comprising:
an active region;
an isolation region on a side surface of the active region;
a gate structure within a gate trench intersecting the active region and extending into the isolation region;
a first impurity region and a second impurity region disposed within the active region on opposite sides of the gate structure and spaced apart from each other;
first and second line structures extending parallel with each other and disposed at a higher level than the gate structure;
a contact structure including a plug pattern disposed between the first and second line structures and electrically connected to the first impurity region, and a pad pattern on the plug pattern and electrically connected to the plug pattern;
a plurality of spacer structures, wherein each of the plurality of spacer structures is disposed on a corresponding side surface of side surfaces of the first and second line structures;
an insulating separation pattern covering at least a portion of a side surface of the pad pattern;
a protective layer, wherein at least a portion of the protective layer is disposed between the insulating separation pattern and the pad pattern; and
a data storage structure on the pad pattern,
wherein the first line structure includes a first bit line including a bit line contact portion electrically connected to the second impurity region, and a first insulating capping pattern on the first bit line,
wherein the second line structure includes a second bit line and a second insulating capping pattern on the second bit line,
wherein the first line structure has a first side surface facing the second line structure,
wherein the second line structure has a second side surface facing the first line structure,
wherein the plurality of spacer structures include a first spacer structure on the first side surface of the first line structure and a second spacer structure on the second side surface of the second line structure,
wherein the first spacer structure is disposed between the contact structure and the first line structure,
wherein the second spacer structure is disposed between the contact structure and the second line structure,
wherein the first spacer structure includes:
a first internal spacer;
a first external spacer; and
a first air gap between the first internal spacer and the first external spacer,
wherein the second spacer structure includes:
a second internal spacer;
a second external spacer; and
a second air gap between the second internal spacer and the second external spacer,
wherein the first internal spacer is adjacent to or contacting the first side surface of the first line structure,
wherein the first external spacer is adjacent to or contacting the contact structure,
wherein the second internal spacer is adjacent to or contacting the second side surface of the second line structure,
wherein the second external spacer is adjacent to or contacting the contact structure,
wherein the insulating separation pattern seals an upper portion of the first air gap,
wherein the plurality of spacer structures further include an upper insulating spacer disposed between the pad pattern and the second insulating capping pattern and defining an upper portion of the second air gap,
wherein the pad pattern includes a portion vertically overlapping the second insulating capping pattern and disposed on the second insulating capping pattern, and
wherein the first internal spacer, the first external spacer, the second internal spacer, and the second external spacer exposed by the first air gap or the second air gap include an oxide.

20. The semiconductor device of claim 19,
wherein at least one of the first internal spacer, the first external spacer, the second internal spacer, and the second external spacer exposed by the first air gap or the second air gap includes a first region including the oxide and a second region including nitride or carbonitride,
wherein the oxide includes oxynitride or oxycarbonitride, and
wherein the first region is disposed between the first air gap or the second air gap and the second region.
